(19) United States
(12) Patent Application Publication
(10) Pub. No.: US 2026/0268030 A1
(43) Pub. Date: Sep. 10, 2026

(54) WEARABLE PROTECTIVE GEAR MODELING METHOD AND SYSTEM, ELECTRONIC DEVICE, AND READABLE STORAGE MEDIUM

(71) Applicant: THE HONG KONG RESEARCH INSTITUTE OF TEXTILES AND APPAREL LIMITED, Kowloon, Hong Kong (CN)

(72) Inventors: Xu SONG, Hong Kong (CN); Junhao DING, Hong Kong (CN); Haoming MO, Hong Kong (CN); Yijian YANG, Hong Kong (CN)

(73) Assignee: THE HONG KONG RESEARCH INSTITUTE OF TEXTILES AND APPAREL LIMITED, Kowloon, Hong Kong (CN)

(21) Appl. No.: 19/165,573

(22) PCT Filed: Nov. 13, 2023
(86) PCT No.: PCT/CN2023/131176

§ 371 Date: Sep. 15, 2025

(51) Int. Cl. G06F 30/10

(52) U.S. Cl. CPC G06F 30/10

(57) ABSTRACT

A wearable protective gear modeling method and system, an electronic device, and a readable storage medium, wherein the wearable protective gear modeling method comprises: carrying out three-dimensional scanning on a target body part of a wearer and modeling to generate a lattice-structured protective gear model; carrying out porosification on the lattice-structured protective gear model; on the basis of the positions of lattices in a modeling space, dividing the lattices into surface lattices, edge lattices and internal lattices respectively; filling the surface lattices, the edge lattices and the internal lattices with first porous structures, second porous structures and third porous structures respectively, to obtain a porous protective gear model having a smooth curved surface, wherein the porous protective gear model can be directly used in production and manufacturing of protective gears.

### FIELD

The present disclosure relates to the field of wearable product design and modeling, and in particular to a wearable protective gear modeling method, system, an electronic device, and a readable storage medium.

### BACKGROUND

Wearable protective gear is used to mitigate physical injuries of a user which are caused by accidents during work, activities, or sports. The wearable protective gear includes products such as knee pads, elbow pads, buttocks pads, hip pads, foot pads, helmets, which generally absorb impact energy on body parts caused by external environments through soft pads or hard pads for the purpose of shock absorption. A conventional protective gear is bulky in design for good energy absorption performance, and is typically manufactured by using an injection molding process, so that the protective gear is heavy and lacks breathability, resulting in a poor wearing experience. In addition, most of the protective gear products in the market are in fixed sizes, without taking into account the differences of users in body shapes, ages, or other factors, failing to fit the user's wearable positions properly. As a result, the protective performance of the protective gear decreases. Therefore, personalized customization has market potential, but manual customization design consumes labor and time.

### SUMMARY

In view of this, according to the present disclosure, a wearable protective gear modeling method, system, an electronic device, and a readable storage medium are provided, to enable a wearable protective gear manufactured in compliance with a protective gear model obtained by the wearable protective gear modeling method to have both excellent shock absorption performance and breathability, alleviating defects of the conventional technology.

In a first aspect, a wearable protective gear modeling method is provided according to the present disclosure. The wearable protective gear modeling method includes:
performing a three-dimensional scan on a wearing position of a user to obtain scanning data;
constructing a latticed protective gear model formed by lattices based on the scanning data;
obtaining face arrays of the lattices in the latticed protective gear model;
determining a surface lattice, an edge lattice, and an internal lattice based on the face arrays of the lattices, where the face array indicates a relative positional relationship of faces that form the lattice, the surface lattice forms a non-edge region of a surface of the latticed protective gear model, the edge lattice forms an edge region of the surface of the latticed protective gear model, and the internal lattice forms an internal structure of the latticed protective gear model; and
filling the surface lattice with a first porous structure, filling the edge lattice with a second porous structure and filling the internal lattice with a third porous structure to obtain a porous protective gear model with a smooth curved surface.

In an embodiment, the constructing a latticed protective gear model based on the scanning data includes:
constructing a solid model of a protective gear and a three-dimensional lattice structure of the protective gear based on the scanning data; and
mapping the three-dimensional lattice structure of the protective gear to the solid model of the protective gear to obtain the latticed protective gear model.

In an embodiment, the constructing a three-dimensional lattice structure of the protective gear based on the scanning data includes:
constructing a two-dimensional mesh region of the protective gear based on the scanning data; and
extruding the two-dimensional mesh region of the protective gear to obtain the three-dimensional lattice structure of the protective gear.

In an embodiment, the constructing a two-dimensional mesh region of the protective gear based on the scanning data includes:
constructing a two-dimensional contour of the protective gear based on the scanning data;
generating, through a triangulation algorithm, a two-dimensional triangular mesh region bounded by the two-dimensional contour of the protective gear and filled with first triangular meshes;
reconstructing a connection between the first triangular meshes in the two-dimensional triangular mesh region to generate a hybrid mesh region filled with second triangular meshes and first quadrilaterals;
subdividing the second triangular meshes and the first quadrilateral meshes to generate a quadrilateral mesh region filled with second quadrilateral meshes; and
mapping the quadrilateral mesh region into the two-dimensional contour of the protective gear to output the two-dimensional mesh region of the protective gear.

In an embodiment, the first porous structure is an implicit surface provided with a surface plane, and the construction of the surface plane enables the porous protective gear model to have a smooth curved surface.

In an embodiment, the first porous structure is a triply periodic minimal surface with a surface plane.

In an embodiment, a process for generating the first porous structure includes:
generating a first porous structure body through an implicit surface modeling method;
determining a plane where a first pore is located, where the first pore is located on the first porous structure body and faces the surface of the latticed protective gear model;
constructing a first quadrilateral plane in the plane where the first pore is located;
generating a first trimming region by using an implicit function representation of the first porous structure body, and removing the first trimming region from the first quadrilateral plane to form a first contour, where the first contour matches seamlessly with a contour of the first pore;
cutting four corners of the first quadrilateral plane through subtracting spheres to output a first surface plane, and latticing the first surface plane; and
connecting the latticed first surface plane and the first porous structure body to generate the first porous structure, to cause the first surface plane to form a non-edge portion of the surface of the porous protective gear model.

In an embodiment, the generating a first trimming region by using an implicit function representation of the first porous structure body includes:
calculating an iso-contour line of the implicit function representation of the first porous structure body in a z-plane; and
generating the first trimming region in the first quadrilateral plane based on the iso-contour line.

In an embodiment, a process for generating the first porous structure includes:
establishing a governing equation of the first porous structure expressed as:

$$⌀ ( x , y , z ) = {Φ}_{P} ( x , y , z ) - N * ( z > k * zi ) ,$$

where Φ(x, y, z) represents an implicit function representation of a first porous structure body, N represents a positive number, and k represents a positive number less than 1; and
generating the first porous structure using the governing equation.

In an embodiment, a process for generating the second porous structure includes:
generating a second porous structure body through geometric shape blending using volume distance functions of a cylinder and a sphere;
determining a plane where a second pore is located, where the second pore is located on the second porous structure body and faces the surface of the latticed protective gear model;
constructing a second quadrilateral plane in the plane where the second pore is located;
generating a second trimming region by using a governing equation of the second pore, and removing the second trimming region from the second quadrilateral plane to form a second contour, where the second contour matches seamlessly with a contour of the second pore;
cutting four corners of the second quadrilateral plane through subtracting spheres to output a second surface plane, and latticing the second surface plane;
connecting the latticed second surface plane and the second porous structure body, to cause the second surface plane to form an edge portion of the surface of the porous protective gear model;
generating a joint region by using a governing equation of a porous structure adjacent to the second porous structure body, where the joint region is for connecting the second porous structure with the adjacent porous structure; and
connecting the joint region and the second porous structure body to generate the second porous structure, where the second porous structure includes the second porous structure body, the second surface plane and the joint region.

In an embodiment, the third porous structure is generated through an implicit surface modeling method.

In an embodiment, the third porous structure is a triple periodic minimal surface.

In an embodiment, the wearable protective gear modeling method further includes:
for each lattice of the lattices, obtaining a vertex array of the lattice, where the vertex array represents positional information of corners forming the lattice; and
generating a face array of the lattice based on the vertex array.

In an embodiment, the generating a face array of the lattice based on the vertex array includes:
determining face components forming the lattice based on the vertex array of the lattice;
determining a joint face and a non-joint face of the lattice based on the face components, where the joint face is a face shared by adjacent lattices, and the non-joint face is a face forming the lattice other than the joint face;
representing the joint face and the non-joint face of the lattice in a binary manner, and generating the face array of the lattice based on a result represented in the binary manner.

In a second aspect, a wearable protective gear modeling system is provided according to the present disclosure. The system includes a three-dimensional scanning module, a model latticing module, a lattice locating module and a lattice filling module.

The three-dimensional scanning module is configured to perform a three-dimensional scan on a wearing position of a user to obtain scanning data.

The model latticing module is configured to construct a latticed protective gear model formed by lattices based on the scanning data.

The lattice locating module is configured to obtain face arrays of the lattices in the latticed protective gear model and determine a surface lattice, an edge lattice, and an internal lattice based on the face arrays of the lattices. The face array indicates a relative positional relationship of faces that form the lattice. The surface lattice forms a non-edge region of a surface of the latticed protective gear model, the edge lattice forms an edge region of the surface of the latticed protective gear model, and the internal lattice forms an internal structure of the latticed protective gear model.

The lattice filling module is configured to fill the surface lattice with a first porous structure, fill the edge lattice with a second porous structure and fill the internal lattice with a third porous structure to obtain a porous protective gear model with a smooth curved surface.

In an embodiment, the model latticing module is further configured to:
construct a solid model of the protective gear and a three-dimensional lattice structure of the protective gear based on the scanning data; and
map the three-dimensional lattice structure of the protective gear to the solid model of the protective gear to obtain the latticed protective gear model.

In an embodiment, the model latticing module is further configured to:
construct a two-dimensional mesh region of the protective gear based on the scanning data; and
extrude the two-dimensional mesh region of the protective gear to obtain the three-dimensional lattice structure of the protective gear.

In an embodiment, the model latticing module is further configured to:
construct a two-dimensional contour of the protective gear based on the scanning data;
generate, through a triangulation algorithm, a two-dimensional triangular mesh region bounded by the two-dimensional contour of the protective gear and filled with first triangular meshes;
reconstruct a connection between the first triangular meshes in the two-dimensional triangular mesh region to generate a hybrid mesh region filled with second triangular meshes and first quadrilaterals;
subdivide the second triangular meshes and the first quadrilateral meshes to generate a quadrilateral mesh region filled with second quadrilateral meshes; and
map the quadrilateral mesh region into the two-dimensional contour of the protective gear and output the two-dimensional mesh region of the protective gear.

In an embodiment, the above wearable protective gear modeling system further includes a porous structure generation module configured to generate the first porous structure, the second porous structure, and the third porous structure for filling the lattices.

In an embodiment, for generating the first porous structure, the porous structure generation module is further configured to:
generate a first porous structure body through an implicit surface modeling method, and determine a plane where a first pore is located, where the first pore is located on the first porous structure body and faces the surface of the latticed protective gear model;
construct a first quadrilateral plane in the plane where the first pore is located, generate a first trimming region by using an implicit function representation of the first porous structure body, remove the first trimming region from the first quadrilateral plane to form a first contour, where the first contour matches seamlessly with a contour of the first pore, cut four corners of the first quadrilateral plane through subtracting spheres to output a first surface plane, and lattice the first surface plane; and
connect the latticed first surface plane and the first porous structure body to generate the first porous structure, to cause the first surface plane to form a non-edge portion of the surface of the latticed protective gear model.

In an embodiment, the porous structure generation module is further configured to:
calculate an iso-contour line of the implicit function of the first porous structure body in a z-plane; and
generate the first trimming region in the first quadrilateral plane based on the iso-contour line.

In an embodiment, for generating the first porous structure, the porous structure generation module is further configured to:
establish a governing equation of the first porous structure expressed as:

$$⌀ ( x , y , z ) = {Φ}_{P} ( x , y , z ) - N * ( z > k * zi ) ,$$

where Φ(x, y, z) represents an implicit function representation of a first porous structure body, N represents a positive number, and k represents a positive number less than 1; and
generate the first porous structure using the governing equation.

In an embodiment, for generating the second porous structure, the porous structure generation module is further configured to:
generate a second porous structure body through geometric shape blending using volume distance functions of a cylinder and a sphere;
determine a plane where a second pore is located, where the second pore is located on the second porous structure body and faces the surface of the latticed protective gear model;
construct a second quadrilateral plane in the plane where the second pore is located, generate a second trimming region by using a governing equation of the second pore, remove the second trimming region from the second quadrilateral plane to form a second contour, where the second contour matches seamlessly with the contour of the second pore, cut four corners of the second quadrilateral plane through subtracting spheres to output a second surface plane, and connect latticed second surface plane and the second porous structure body, to cause the second surface plane to form an edge portion of the surface of the latticed protective gear model; and
generate a joint region by using a governing equation of a porous structure adjacent to the second porous structure body, where the joint region is for connecting the second porous structure with the adjacent porous structure, and connect the joint region and the second porous structure body to generate the second porous structure, where the second porous structure includes the second porous structure body, the second surface plane and the joint region.

In an embodiment, for generating the third porous structure, the porous structure generation module is further configured to:
generate the third porous structure through an implicit surface modeling method.

In an embodiment, the above wearable protective gear modeling system further includes a face array generation module, and the face array generation module is configured to:
for each lattice of the lattices,
obtain a vertex array of the lattice, where the vertex array represents positional information of vertices forming the lattice; and
generate a face array of the lattice based on the vertex array.

In an embodiment, the face array generation module is further configured to:
determine face components forming the lattice based on the vertex array of the lattice;
determine a joint face and a non-joint face of the lattice based on the face components, where the joint face is a face shared by adjacent lattices, and the non-joint face is a face forming the lattice other than the joint face;
represent the joint face and the non-joint face of the lattice in a binary manner, and generate the face array of the lattice based on a result represented in the binary manner.

In a third aspect, an electronic device is provided according to the present disclosure. The electronic device includes a memory storing a computer-executable instruction and a processor. The computer-executable instruction, when executed by the processor, causes the electronic device to perform the wearable protective gear modeling method provided in the first aspect.

In a fourth aspect, a readable storage medium is provided according to the present disclosure. The readable storage medium stores a computer-executable program, where the computer-executable program, when being executed, performs the wearable protective gear modeling method provided in the first aspect.

In a fifth aspect, a wearable protective gear is further provided according to the present disclosure. The wearable protective gear is manufactured by using an additive manufacturing technology. In an additive manufacturing process, a porous protective gear model generated by the wearable protective gear modeling method provided in the first aspect is configured as a digital model.

As can be seen from the above technical solutions, the present disclosure has the following beneficial effects.

A wearable protective gear modeling method, system, an electronic device, and a readable storage medium are provided according to the present disclosure. According to the wearable protective gear modeling method, a three-dimensional scan is performed on a wearing position of a user to obtain scanning data, and a latticed protective gear model is constructed by modeling based on the scanning data. The latticed protective gear model is converted into a porous protective gear model by filling the lattices in the latticed protective gear model with different porous structures according to different positions of the lattices. The obtained porous protective gear model is directly used for production and manufacture of the protective gear. According to the present disclosure, the advantages of high porosity and high specific strength of the porous structure are utilized, enabling the wearable protective gear with excellent energy absorption capacity, which can achieve good shock absorption and impact protection when subjected to external forces. The high porosity of the porous structure reduces the overall density of the protective gear, making it more breathable and greatly improving the wearing experience. The porous protective gear model reduces materials in non-critical regions, thereby reducing the use of manufacturing materials, decreasing the weight of the wearable protective gear, realizing the lightweight design of the product, and additionally lowering the cost of raw materials. Different from the conventional manufacturing method using one model, with the modeling method provided in the present disclosure, a personalized and producible protective gear model is rapidly established according to the user's body shape data, so that the protective gear fits better with the wearing position of the user and provides a more comfortable wearing feeling.

### BRIEF DESCRIPTION OF THE DRAWINGS

Hereinafter drawings to be applied in embodiments of the present disclosure or in the conventional technology are briefly described, in order to illustrate technical solutions according to embodiments of the present disclosure or in the conventional technology more clearly. Apparently, the drawings in the following descriptions are only some embodiments of the present disclosure, and other drawings may be obtained by those skilled in the art based on the provided drawings without any creative effort.

FIG. 1 shows types of porous structures found in nature according to the conventional technology;

FIG. 2 is a flowchart of an execution process of a wearable protective gear modeling method according to an embodiment of the present disclosure;

FIG. 3 shows an example of determining a lattice type based on a face array of a lattice according to an embodiment of the present disclosure, where FIG. 3(a) shows a modeling space formed by 27 hexahedral lattices, FIG. 3(b) shows a spatial geometric structure of a hexahedral lattice, FIG. 3(c) to FIG. 3(f) respectively show the locations of a corner lattice, an edge lattice, a surface lattice, and an internal lattice in the modeling space shown in FIG. 3(a).

FIG. 4 is a schematic diagram of a process for generating a first surface plane based on a TPMS unit cell according to an embodiment of the present disclosure, where FIG. 4(a) shows a process of trimming a plane, located at z=zi, of a hexahedron by a region defined by the TPMS implicit function representation, FIG. 4(b) and FIG. 4(c) show a process of cutting corners of the plane of the hexahedron in FIG. 4(a) through subtracting spheres, and FIG. 4(d) shows a first surface plane based on the TPMS unit cell;

FIG. 5 shows a process for generating a first porous structure based on the TPMS unit cell according to an embodiment of the present disclosure;

FIG. 6 shows three types of first porous structures that are directly generated by modifying a governing equation of a porous structure according to an embodiment of the present disclosure;

FIG. 7 is a schematic diagram of a process for generating a second porous structure according to an embodiment of the present disclosure, where FIG. 7(a) shows a second porous structure body that is generated by performing geometric shape blending on cylinders and a sphere using volume distance functions, FIG. 7(b) shows a second surface plane connected with a second porous structure body, FIG. 7(c) shows a joint region connected with the second porous structure body, and FIG. 7(d) shows the second porous structure connected with an adjacent porous structure in a watertight manner via the joint region;

FIG. 8 is a schematic diagram of a process for filling porous structures to adjacent lattices A and B according to an embodiment of the present disclosure, where FIG. 8(a) shows an exemplary scenario of defining a coordinate system within a porous structural unit, FIG. 8(b) shows an example of a positional relationship of the adjacent lattices A and B in a coordinate system, FIG. 8(c) shows a connection between identical porous structures in adjacent lattices, and FIG. 8(d) shows a connection between different porous structures in adjacent lattices;

FIG. 9 shows a process for generating a latticed hip pad model 306 according to an embodiment of the present disclosure;

FIG. 10 is a flowchart of modeling a porous hip pad model according to an embodiment of the present disclosure;

FIG. 11 shows a process for constructing a two-dimensional mesh region 304 of a hip pad according to an embodiment of the present disclosure;

FIG. 12 shows a process for converting the latticed hip pad model 306 generated in FIG. 9 into a porous structure;

FIG. 13 shows a comparison of a porous hip pad model provided according to an embodiment of the present disclosure with a porous hip pad model generated based on a conventional modeling method, where the porous hip pad model shown in FIG. 13(a) has a smooth curved surface, and the porous hip pad model shown in FIG. 13(b) is only filled with a conventional implicit surface and is not formed with a smooth curved surface;

FIG. 14 is a schematic structural diagram of a wearable protective gear modeling system 600 according to an embodiment of the present disclosure;

FIG. 15 is a schematic structural diagram of a wearable protective gear modeling system according to another embodiment of the present disclosure, which is based on the wearable protective gear modeling system 600 in FIG. 14;

FIG. 16 shows a block diagram of a hardware structure of an electronic device according to an embodiment of the present disclosure.

### DETAILED DESCRIPTION OF THE EMBODIMENTS

The technical solutions according to the embodiments of the present disclosure will be described clearly and completely as follows in conjunction with the drawings in the embodiments of the present disclosure. It is apparent that the described embodiments are only some of the embodiments according to the present disclosure, rather than all the embodiments. All other embodiments obtained by those skilled in the art based on the embodiments of the present disclosure without any creative work fall within the protection scope of the present disclosure.

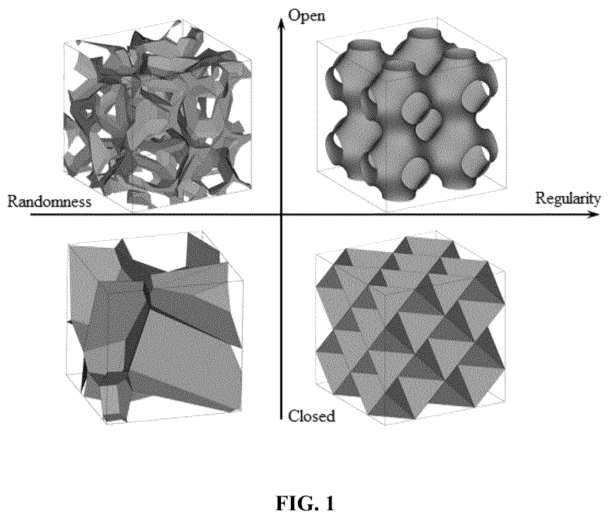

Porous structures are widely found in nature, such as plant roots and stems, animal skeletons, sponges and corals. FIG. 1 shows four common types of porous structures. Based on two dimensions: openness and arrangement of pores, the porous structures may be roughly categorized into four types: regular open, regular closed, random open and random closed. A porous structure features a large number of pores, and the shape, combination, and arrangement of these pores provide excellent properties unique to the structure, such as lightweight and material saving, buffering and vibration damping, and silencing and heat insulation.

A random porous structure is the most common, and is characterized by low density and high specific surface area. However, mechanical properties of the random porous structure are poorer than those of a regular porous structure. The performance adjustment and control of the random porous structure have significant uncertainty due to the random distribution of pores, leading to a high computation complexity in modeling. The performance control of regular porous structures is achieved more easily in applications. Regular closed porous structures have closely arranged pores, excellent anti-pressure capability but poor breathability, and they are not applicable for products such as wearable protective gear that requires high breathability. Regular open porous structures combine excellent mechanical properties and breathability. The performance control of the regular open porous structures is achievable due to regular distribution of pores, and the regular open porous structures enable a lightweight design of the structures, making them the first choice for products such as a wearable protective gear.

Currently, the regular porous structure may be categorized into a plate structure, a column (pole) structure and a shell structure based on basic units forming the regular porous structure. The plate structure achieves an in-plane stress distribution state through an appropriate plate arrangement, thereby reaching a theoretical strength limit. Due to manufacturing constraints, the plate structure is typically perforated, which reduces mechanical properties. The column (pole) structure is prone to stress concentration at a joint, and its mechanical properties are relatively low. The shell structure usually exhibits intermediate mechanical properties, and its open lattice structure meets the high breathability requirements of the products such as the wearable protective gear. In the field of wearable products, it has been a trend to personalize products according to the user's body shape, age, usage habits and other aspects. In particular, wearable protective gear requires a high fit between the protective gear and the user's wearing positions; otherwise, the energy absorption capacity of the wearable protective gear cannot be fully utilized. However, most of the conventional personalized customizations of wearable products rely on manual modification, which consumes more time and labor, thereby limiting production efficiency.

Aspects of the present disclosure relate to a wearable protective gear modeling method, system, an electronic device, and a readable storage medium. According to the modeling method in the present disclosure, a wearable protective gear model that combines excellent mechanical properties and breathability while meeting the personalized requirements of the user is designed. The design process features intelligence and automation. The design efficiency is improved and an obtained porous protective gear model can be directly applied to production and manufacturing.

As exemplified herein, the wearable protective gear modeling method provided according to the present disclosure may be applied to computing devices such as computer systems/servers, which can operate in conjunction with numerous other general-purpose or specialized computing system environments or configurations. Well-known computing systems, environments and/or configurations suitable for use with the computing devices such as the computer systems/the servers may include but are not limited to: an embedded platform, a personal computer system, a server computer system, a thin client device, a thick client device, a handheld or laptop device, a microprocessor-based system, a set-top box, programmable consumer electronics, a network personal computer, a minicomputer system, a mainframe computer system, and distributed cloud computing environments that include any of the above systems, and the like.

The wearable protective gear modeling method provided according to the present disclosure may be implemented by a software program running within a computing device as described above. The software program may be a pre-designed executable computer-readable code or an algorithmic model trained with data.

The above computing devices may be connected to the devices in a production and manufacturing process via a communication network. The communication network includes a wireless network and a wired network, where the wireless network includes one or more of a wireless wide area network, a wireless local area network, a wireless metropolitan area network, a wireless personal network, and the like.

Terms used herein to describe positional relationships such as “surface”, “backside portion”, “internal portion” refer to portions of a three-dimensional object, i.e. a protective gear model that is either in contact with the external environment or not in the modeling environment. When a finished product manufactured based on a model is worn by a user, these terms also denote portions such as a portion of a knee pad that is either in contact with the external environment or not. For example, a portion of the knee pad that is in contact with a wearing position is denoted as the surface, a portion of the knee pad that is on the opposite side of the surface and is in contact with the external environment is denoted as the backside portion, and a portion of the knee pad that is not in contact with the wearing position nor the external environment is denoted as the internal portion.

Relationship terms herein such as “first”, “second” and the like are only used to distinguish one entity or operation from another, rather than necessitate or imply that any such actual relationship or order exists between these entities or operations. Furthermore, terms “include”, “comprise” or any other variants thereof are intended to be non-exclusive. Therefore, a process, method, article or device including a series of elements includes not only the elements but also other elements that are not enumerated or other elements inherent to such process, method, article or device. Unless expressively limited, the statement “including a . . . ” does not exclude the case that other identical elements may exist in the process, method, article or device including the series of elements.

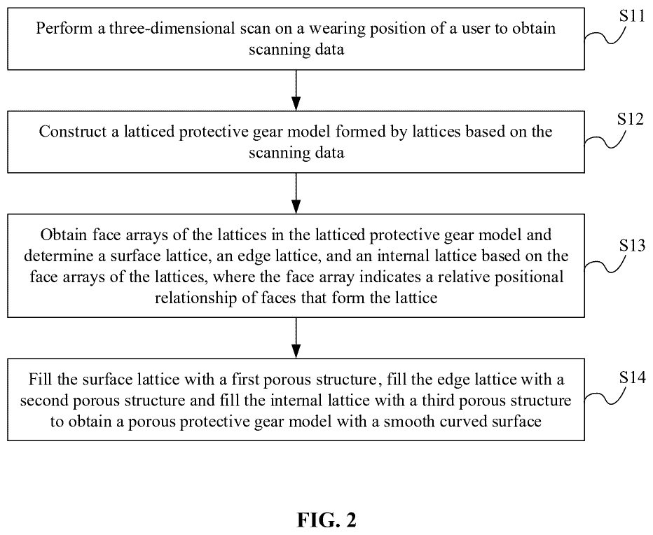

As shown in FIG. 2, FIG. 2 is a flowchart of an execution process of a wearable protective gear modeling method according to an embodiment of the present disclosure. The process may include steps S11 to S14.

In step S11, a three-dimensional scan is performed on a wearing position of a user to obtain scanning data.

In an embodiment, the scanning data is obtained by scanning the wearing position of the user through various well-known three-dimensional scanning methods. The wearing position may be a head, an elbow, a knee, a sole of the foot, a buttock and the like, and critical information of the wearing position of the user, such as the length, the width, the height, the curvature, the curved surface structure is accurately obtained through the three-dimensional scan. The obtained three-dimensional scanning data may be stored in the form of point cloud data.

In step S12, a latticed protective gear model formed by lattices is constructed based on the scanning data.

In an embodiment, reconstructing a model on a computing device based on the scanning data is a common modeling method. An inner surface of the model is reconstructed by extracting geometric features from the scanning data to fit a wearing position, and surfaces of the model is determined based on a predetermined relationship between user's personalized features such as a body shape, a weight, a type of movement (activity), and a personal preference.

For product model design based on a porous structure, it is an implementable way to lattice a solid model, that is, to partition the solid model into basic units through voxelization. Each of the basic units is referred to as a lattice. A lattice is a repeated or non-repeated three-dimensional collection of connected nodes. In its simplest form, multiple lattice nodes are connected with each other by beams, and the collection of beams and nodes forms a regular and repeated three-dimensional shape. All lattices are filled with porous structures to form a porous wearable protective gear.

In aspects provided according to the present disclosure, instead of a porous structure being directly mapped into a solid model, the solid model is first partitioned into several uniformly sized lattices, and then the different lattices are filled with different porous structures according to the structure of the wearable protective gear.

In an embodiment, step S12 may include the following step S121 and step S122.

In step S121, a solid model of a protective gear and a three-dimensional lattice structure of the protective gear are constructed based on the scanning data.

In an embodiment, the solid model of the protective gear is a fusion model constructed by performing internal structure reconstruction and surface reconstruction based on the scanning data obtained in step S11, which completely presents structural features of the wearing position. The three-dimensional structure of the protective gear is constructed as a three-dimensional lattice region bounded by a contour of the wearing position, with uniformly distributed and evenly sized lattices.

The above construction process of the three-dimensional lattice structure of the protective gear includes: offsetting two-dimensional lattice coordinates in an extrusion direction and constructing three-dimensional lattices based on the two-dimensional lattices before and after the offset. This process may also be implemented by various commercial modeling software programs. To increase the efficiency of the modeling, an execution process for generating a two-dimensional mesh region of the protective gear is provided according to an embodiment of the present disclosure, and the process includes steps S1211 to S1215.

In step S1211, a two-dimensional contour of the protective gear is constructed based on the scanning data.

In step S1212, a two-dimensional triangular mesh region filled with first triangular meshes and bounded by the two-dimensional contour of the protective gear is generated by using a triangulation algorithm (Delaunay algorithm).

In step S1213, a connection between the first triangular meshes in the two-dimensional triangular mesh region is reconstructed to generate a hybrid mesh region filled with second triangular meshes and first quadrilaterals.

In step S1214, the second triangular meshes and the first quadrilateral meshes are subdivided to generate a quadrilateral mesh region filled with second quadrilateral meshes.

In step S1215, the quadrilateral mesh region is mapped into the two-dimensional contour of the protective gear and output the two-dimensional mesh region of the protective gear.

In step S122, the three-dimensional lattice structure of the protective gear is mapped into the solid model of the protective gear to obtain the latticed protective gear model.

The solid model of the protective gear is latticed by step S122, and the obtained latticed protective gear model is almost fully fit to the wearing position. The latticed protective gear model is converted into a porous structure in a subsequent step, that is, each lattice is filled with a porous structural unit, and porous structures of adjacent lattices feature smooth junctions and full connectivity. A size, distribution and shape of pores in a porous structure affect the performance of the porous structure, and the size and density of the lattice is controlled in a process of latticing to control the performance of the porous structure.

In step S13, face arrays of the lattices in the latticed protective gear model are obtained, and a surface lattice, an edge lattice, and an internal lattice are determined based on the face arrays of the lattices. The face array indicates a relative positional relationship of faces that form the lattice.

In an embodiment, to enhance the fit between the wearable protective gear and the wearing position and wearing comfort, in a process of converting the latticed protective gear model into a porous structure, a filling manner is provided according to the embodiments of the present disclosure. In the filling manner, the porous structures filled in the lattices are determined based on a relative position of the protective gear, when being worn, to the wearing position, so as to enable the porous protective gear model to have a smooth curved surface. The lattices in the latticed protective gear model are divided into surface lattices, edge lattices and internal lattices, with the surface lattices forming a non-edge region of the surface of the modeling space, the edge lattices forming an edge region of the surface of the modeling space, and the internal lattices forming an internal structure of the modeling space. A latticed knee pad model is taken as an example, surface lattices form a non-edge portion of the latticed knee pad model that is in contact with the external environment, edge lattices form an edge portion of the latticed knee pad model that is in contact with the external environment, for example, a joint between two flat surfaces, and internal lattices form a portion of the latticed knee pad model that is not in contact with the external environment.

For example, faces of the lattices are divided into a joint face and a non-joint face, where the joint face is a face shared by adjacent lattices, and the non-joint face is a face forming the lattice other than the joint face. The joint face and the non-joint face of the lattices are represented in a binary manner, and face arrays of the lattices are generated based on a result of the interfaces represented in the binary manner.

Furthermore, there is no particular limitation on the morphology of the lattices, and the lattices may be common columns, tetrahedrons, hexahedrons, and the like.

A hexahedral lattice is taken as an example, one lattice consists of six faces, and (X+, X−, Y+, Y−, Z+, Z−) represents the relative positional relationship of the six face components of the lattice based on relative positions of the faces in a coordinate system. In a process of representing the lattice in a binary manner, 0 represents the joint face and 1 represents the non-joint face, so that the face array of the surface lattice is represented as [0, 0, 0, 1, 0, 0] or [0, 1, 0, 0, 0, 0], the face array of the edge lattice is represented as [1, 0, 0, 1, 0, 0], and the face array of the internal lattice is represented as [0, 0, 0, 0, 0, 0]. The type of lattices and connectivity between the lattices are determined based on the face arrays of the lattices, so that different porous structures are selected to fill the lattices.

In an embodiment, the hexahedral lattice is taken as an example for illustrating the process of determining the surface lattice, the edge lattice, and the internal lattice based on the face arrays of the lattices in step S13.

A latticed modeling space is partitioned into various hexahedrons. Each of the hexahedrons has 8 vertices, and vertex arrays of the lattices are obtained. The face arrays of the lattices are generated based on the vertex arrays. A modeling space including 27 hexahedral lattices is taken as an example herein for illustrating.

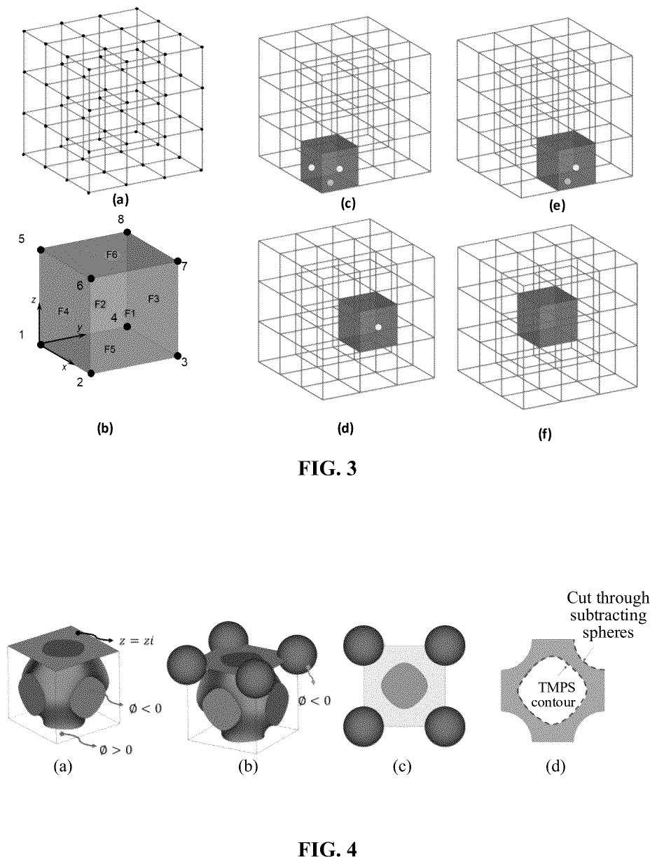

As shown in FIG. 3(a), each of the 27 lattices is treated as a hexahedron with 8 vertices. The vertices are numbered with serial numbers from 1 to 8, and the lattice is represented by a vertex array [1, 2, 3, 4, 5, 6, 7, 8]. According to a case shown in FIG. 3(b), coordinates of all vertices are determined based on the vertex array, thereby determining the shape of the lattice and position of the lattice in the modeling space. In other embodiments, a lattice may be directly represented by a vertex coordinate set.

As shown in FIG. 3(b), a hexahedral lattice has six faces. Based on the vertex array [1, 2, 3, 4, 5, 6, 7, 8], six plane lattices of the six faces, including [6, 2, 3, 7], [4, 1, 5, 8], [3, 4, 8, 7], [1, 2, 6, 5], [5, 6, 7, 8], and [1, 4, 3, 2] are determined. These six faces are in a plane positional relationship which is represented by the (X+, X−, Y+, Y−, Z+, Z−).

The joint face provided according to aspects of the present disclosure is a face shared by adjacent lattices, and the non-joint face is a face other than the joint face of the lattice. 0 represents the joint face and 1 represents the non-joint face, so that a binarized face array is determined for each lattice. FIG. 3(c) shows a corner lattice of the modeling space with a face array represented as [1, 0, 0, 1, 1, 0]. FIG. 3(d) shows a surface lattice of the modeling space with a face array represented as [0, 0, 0, 1, 0, 0]. FIG. 3(e) shows an edge lattice of the modeling space with a face array represented as [1, 0, 0, 1, 0, 0]. FIG. 3(f) shows an internal lattice of the modeling space with a face array represented as [0, 0, 0, 0, 0, 0]. In some embodiments, the corner lattice may be regarded as a specialized case of an edge lattice.

Therefore, a position of a lattice in the modeling space is determined based on the binarized face array of the lattice, thereby determining the surface lattice, the edge lattice, and the internal lattice.

It can be understood that the above illustrated face array representation is only an example provided according to the embodiments of the present disclosure for illustrating working principles thereof, and other ways of representing the type of the lattices may be used according to aspects of the present disclosure. Other exemplary cases, such as a case that the joint face is represented by 1 and the non-joint face is represented by 0, or they are directly represented by vertex coordinates of the lattice, fall within the protection scope of the present disclosure.

In step S14, the surface lattice is filled with a first porous structure, the edge lattice is filled with a second porous structure and the internal lattice is filled with a third porous structure to obtain a porous protective gear model with a smooth curved surface.

In an embodiment, the porous structure is generated through an implicit surface modeling method. An implicit surface does not directly reflect information of points on a curved surface, but only describes a relationship satisfied by all points on the curved surface. Common implicit surfaces include an algebraic surface, a distance function, a level set, and a fractal geometry. Implicit surfaces have great advantages in determining internal and external relationships, smooth model fusion, and representing a complex topological relationship. The shape of the porous structure is adjusted and controlled by using a function representation parameter of the implicit surface, and the generated porous structure is smooth, regular, and periodically varies in the direction of a coordinate axis, ensuring a continuous and controllable modeling process for the protective gear model. Additionally, the smooth surface minimizes stress concentration, allowing the finished protective gear to achieve excellent specific strength.

In most implicit surfaces, connectivity regions are only at edges of curved surface units and do not form a continuous surface plane. To enhance the smoothness and wear resistance of the finished protective gear and to improve the wearing comfort, compared to the conventional porous structure, surface planes are increased for forming a seamless curved surface of the protective gear in the wearable protective gear modeling method provided according to the aspects of the present disclosure. It can be understood that, since both the surface lattice and the edge lattice constitute the surface region of the latticed protective gear model, porous structures for filling the surface lattice and the edge lattice are provided with surface planes.

For example, a triply periodic minimal surface (TPMS) constructed by using the implicit surface modeling method is a typical representative of regular porous structures. The TPMS is smooth and continuous, with periodic variations in X, Y, and Z directions, enabling the construction of fully connected, highly porous structures without self-intersections. The TPMS has an explicit implicit function representation, and geometric features of the curved surface may be changed by adjusting the implicit parameter, resulting in a high degree of freedom in modeling. Typical TPMS structures include P units, D units, G units, as well as shell-P units, shell-D units, shell-G units, and the like. Geometric features of TPMS unit cells, such as the size and density of the pores, are controlled through an implicit representation Φ(x, y, z)=c.

In some embodiments, generating the first porous structure through the implicit surface modeling method includes:
generating a first porous structure body through an implicit surface modeling method, and determining a plane where a first pore is located, where the first pore is located on the first porous structure body and faces the surface of the latticed protective gear model;
constructing a first quadrilateral plane in the plane where the first pore is located, generating a first trimming region by using an implicit function representation of the first porous structure body, removing the first trimming region from the first quadrilateral plane to form a first contour, where the first contour matches seamlessly with a contour of the first pore, and cutting four corners of the first quadrilateral plane through subtracting spheres to obtain a first surface plane, and latticing the first surface plane; and
connecting the latticed first surface plane and the first porous structure body to generate the first porous structure, to cause the first surface plane to form a non-edge portion of the surface of the latticed protective gear model.

In an embodiment, the first trimming region may be generated by: calculating an iso-contour line of the implicit function representation of the first porous structure body in a z-plane; and generating the first trimming region in the first quadrilateral plane based on the iso-contour line.

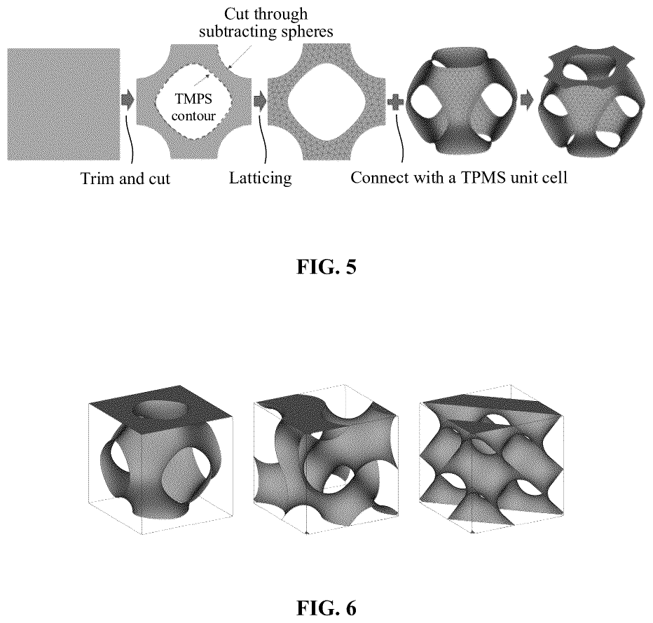

For example, the TPMS unit cell serves as the first porous structure body. A typical TPMS unit cell is not formed with a surface plane, with connected regions existing only in edges of the TPMS unit cells. FIG. 4 shows a process for generating a first surface plane based on a TPMS unit cell. The modeling space is divided into two independent subspaces Ø>0 and Ø<0, via the implicit function representation Ø=0 of the TPMS, where Ø>0 indicates an external region and Ø<0 indicates an internal region of the curved surface. FIG. 4(a) shows a process of trimming a plane, located at z=zi, of a hexahedron by a region defined by the TPMS implicit function representation. The trimming region is obtained by calculating an iso-contour line of the implicit function representation at z=zi, thereby forming a trimmed contour which is the same as a pore contour of the TPMS in a plane of the modeling space. Since the trimming region on the plane is derived from the implicit function representation of the TPMS, the plane matches seamlessly with the TPMS unit cell. FIG. 4(b) and FIG. 4(c) show a process of cutting corners of the plane of the hexahedron through subtracting spheres. A surface plane as shown in FIG. 4(d) is obtained through the in-plane trimming and corner cutting. As shown in FIG. 5, by connecting the surface plane generated in FIG. 4 with the TPMS unit cell, a first porous structure for filling a surface lattice is generated.

Other porous structures provided with surface planes may be similarly generated and are not enumerated herein.

In an embodiment, for generating the first porous structure through the implicit surface modeling method, in addition to the above trimming and cutting the plane, a porous structure with a surface plane may also be directly generated by modifying a functional representation of an implicit surface. A governing equation is set for the first porous structure and is expressed as Ø(x, y, z)=Φ_{P}(x, y, z)−N*(z>k*zi). By using the governing equation, a surface plane at z=zi is generated while generating a porous structure body. Φ(x, y, z) represents an implicit function representation of an implicit surface, N represents a positive number which is typically set to a large value to accelerate a function value into a negative range, and k represents a positive number less than 1. By applying a governing equation, surface planes may also be generated in the planes where other pores of the implicit surface are located.

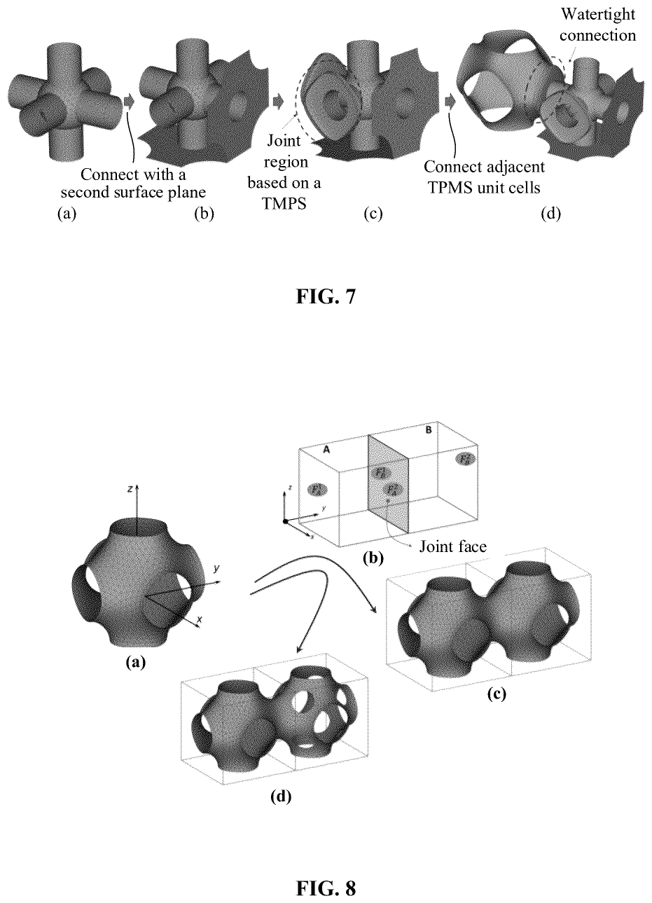

In an embodiment, the TPMS is taken as an example, FIG. 6 shows that for each type of three types of TPMS unit cells, a surface plane and a porous structure body are generated simultaneously by modifying a governing equation of the porous structure. A P unit is taken as an example, in a case that the P unit of the TPMS serves as the porous structure body of a surface lattice, assuming that the implicit function representation of the P unit is Φ_{P}(x, y, z)=cos(ωx)+cos(ωy)+cos(ωz)−0.2, a governing equation of the porous structure filled within the surface lattice may be defined as Ø(x, y, z)=Φ_{P}(x, y, z)−N*(z>k*zi), where N is set to a large positive number, and 0<k<1.

In some embodiments, generating the second porous structure through the implicit surface modeling method may include:
generating a second porous structure body through geometric shape blending using volume distance functions of a cylinder and a sphere;
determining a plane where a second pore is located, where the second pore is located on the second porous structure body and faces the surface of the latticed protective gear model;
constructing a second quadrilateral plane in the plane where the second pore is located, generating a second trimming region by using a governing equation of the second pore, removing the second trimming region from the second quadrilateral plane to form a second contour, where the second contour matches seamlessly with the contour of the second pore, cutting four corners of the second quadrilateral plane through subtracting spheres to output a second surface plane, latticing the second surface plane, and connecting the latticed second surface plane and the second porous structure body, to cause the second surface plane to form an edge portion of the surface of the latticed protective gear model; and
generating a joint region by using a governing equation of a porous structure adjacent to the second porous structure body, where the joint region is for connecting the second porous structure with the adjacent porous structure, and connecting the joint region and the second porous structure body to generate the second porous structure, where the second porous structure includes the second porous structure body, the second surface plane and the joint region.

In an embodiment, edge lattices provided according to aspects of the present disclosure are used to form edge regions of the surface of the latticed protective gear model, where these edge regions feature connection angles of certain degrees. Therefore, the optimal porous structure is not a direct mapping of implicit surfaces with identical governing equations. Instead, geometric shape blending is performed based on volume distance functions of a cylinder and a sphere, and the surface plane of the porous structure body is generated by using an approach similar to the aforementioned surface plane generation method. In order to establish a watertight connection between different implicit surface units, a joint region is generated by using governing equations of adjacent porous structures. The two adjacent porous structures are seamlessly connected with each other via the joint region, ultimately resulting in a second porous structure for filling the edge lattice.

The TPMS is taken as an example for illustrating. FIG. 7 shows a process for generating a second porous structure based on a TPMS unit cell. As shown in FIG. 7(a), the second porous structure body is generated by performing geometric shape blending on cylinders and a sphere using volume distance functions thereof, and porous structure based on the column or beam smoothly transition adjacent surfaces of the protective gear model to improve the fit and wearing comfort of a finished protective gear. FIG. 7(b) shows second surface planes connected with a second porous structure body. Which plane where a pore is located is to be connected to the second surface plane is determined according to a specific lattice connection relationship. FIG. 7(c) shows a joint region connected with a second porous structure body. In this example, the TPMS unit cells are treated as connected adjacent porous structures for illustrating, and a transition between different TPMS unit cells may be determined by a spatial weight function γ whose value ranges from 0 to 1. The transition is expressed using the following sigmoid function:

$${Φ}_{hybrid} = {γΦ}_{TPMS 1} + ( 1 - γ ) {Φ}_{TPMS 2}$$

$$γ = \frac{1}{1 + {e}^{rG ( x , y , z )}}$$

where Φ_{TPMS1} and Φ_{TPMS2} respectively represent implicit function representations of two different TPMS unit cells which are connected, G(x, y, z) represents a governing function describing a transition layer, and r is used to control a width of the transition layer.

In a further embodiment, a non-joint face of the lattice is determined, and then a plane where surface planes of porous structures are located may be determined. Typically, the surface planes of the porous structures, such as the first surface plane and the second surface plane described above, are in the same plane as the non-joint face of the lattice.

In a further embodiment, a third porous structure is configured to fill an internal structure. As the third porous structure is in an internal space of the protective gear mode, it requires no surface plane and serves to maintain lattice connectivity. Thus, the third porous structure is generated as a smooth, fully connected implicit surface using conventional implicit surface modeling methods.

Yield strength and energy absorption capacity of the protective gear are adjusted by modifying the relative density and thickness of the porous structure, to meet individual requirements of different users. For example, an internal lattice is filled with a shell-type porous structural unit with a great thickness, and a surface lattice is filled with a soft porous structural unit with a low density.

In an embodiment, the lattice filling process in step S14 may be implemented as a mapping process based on a shape function, where a porous structure is filled into a lattice by mapping nodes of the porous structure. Similarly, an STL file is taken as an example for illustrating, the modeling space of the porous structure is stored as a set of node coordinates and a connectivity representation of the set of nodes. In a case of keeping the connectivity unchanged, a new STL file is obtained by mapping the node coordinates.

For example, FIG. 8 shows a process for filling porous structures generated by implicit surface modeling into adjacent lattices A and B. FIG. 8(a) shows an exemplary scenario of defining a coordinate system within a porous structural unit. When mapping porous structural units to adjacent lattices A and B in a latticed model illustrated in FIG. 8(b), model integrity preservation requires maintaining identical nodes at lattice joint faces. Therefore, the integrity can be automatically achieved if the two porous structural units have an identical structure with respect to a XOZ plane, as shown in FIG. 8(c), and the integrity can be achieved by enforcing nodes coincidence on the joint face if the porous structural units have different structures, as shown in FIG. 8(d).

A filled porous protective gear model subjected to step S14 has a fully connected and smooth porous structure, and can be directly used for manufacturing of a finished product, for example, using an additive manufacturing technology. The additive manufacturing technology includes but not limited to SLS, DLP, FDM, and other conventional three-dimensional molding technologies.

The three-dimensional latticed protective gear model generated by the above modeling method fully considers the individual requirements of users of different races, genders, body shapes and the like, and is more fitting and comfortable to wear. The conventional protective gears are bulky and typically made of thick energy-absorbing materials, resulting in a poor breathability. In the modeling method provided according to aspects of the present disclosure, a regular porous structure with high porosity is employed, and an implicit surface is further applied, ensuring the protective gear maintains a low overall density while retaining excellent energy absorption capabilities. Applying this porous structure improves the breathability of the protective gear, and thus improving the wearing experience. In addition, the porous structure reduces material usage, resulting in lighter-weight protective gear, lower raw material consumption, reduced production costs, and a more environmentally friendly solution.

A hip pad is taken as an example in the following, to further illustrate a wearable protective gear modeling method provided according to embodiments of the present disclosure.

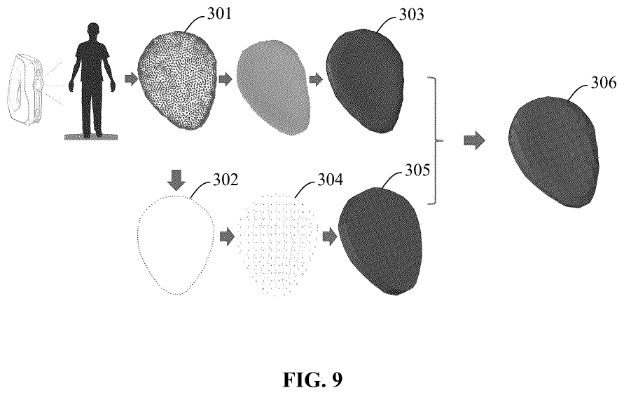

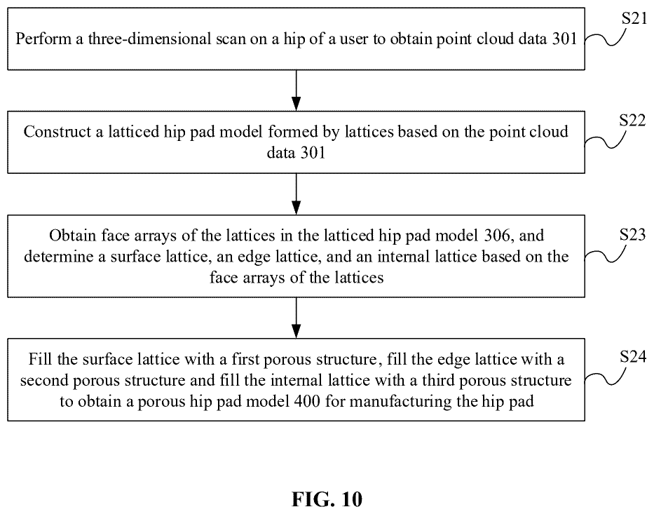

Reference is made to FIG. 9 and FIG. 10, which illustrate processes for generating a latticed hip pad model and a porous hip pad model. FIG. 10 shows steps performed in an entire modeling process, which including step S21 to step S24.

In step S21, a three-dimensional scan is performed on a hip of a user to obtain point cloud data 301.

In step S22, a latticed hip pad model formed by lattices is constructed based on the point cloud data 301.

As specifically shown in FIG. 9, a two-dimensional contour 302 of the hip pad and a solid model 303 of the hip pad are constructed based on the point cloud data 301. The solid model 303 of the hip pad is a fusion model constructed by performing internal structure reconstruction and surface reconstruction based on the point cloud data 301, which completely presents structure features of the hip. A two-dimensional mesh region 304 of the hip pad is obtained by latticing a space within the two-dimensional contour 302 of the hip pad. The two-dimensional mesh region 304 of the hip pad is extruded to obtain a three-dimensional lattice structure 305 of the hip pad. The three-dimensional lattice structure 305 of the hip pad is mapped to the solid model 303 of the hip pad to obtain a latticed hip pad model 306.

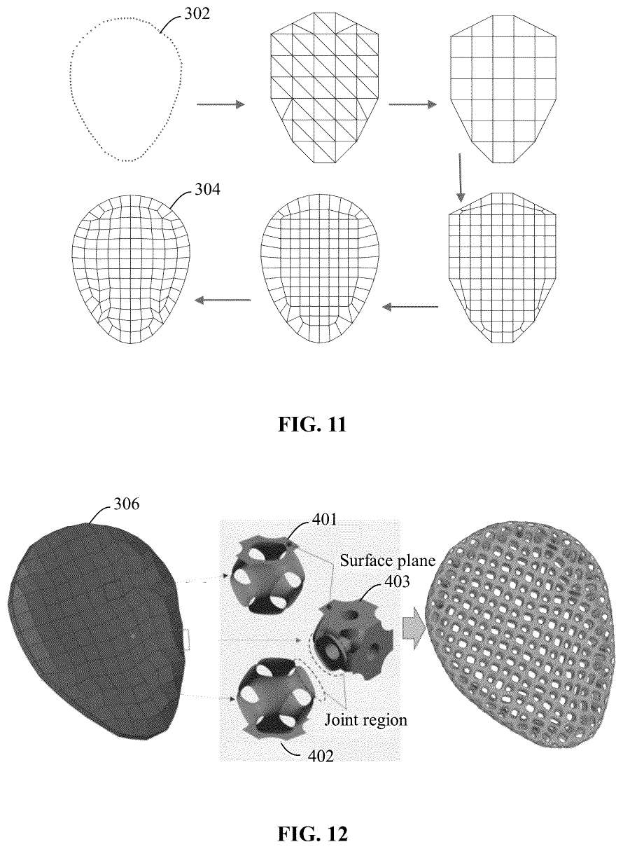

The above process for constructing the two-dimensional mesh region 304 of the hip pad is schematically illustrated in FIG. 11. The specific implementation steps correspond one-to-one with the steps S1211 to S1215 in the aforementioned embodiments, and reference may be made to the above content for detailed description, which is not described here.

In step S23, face arrays of the lattices in the latticed hip pad model 306 are obtained, and a surface lattice, an edge lattice, and an internal lattice are determined based on the face arrays of the lattices. The face array indicates a relative positional relationship of faces that form the lattice. The surface lattice forms a non-edge region of a surface of the latticed hip pad model 306, the edge lattice forms an edge region of the surface of the latticed hip pad model 306, and the internal lattice forms an internal structure of the latticed hip pad model 306.

In step S24, the surface lattice is filled with a first porous structure, the edge lattice is filled with a second porous structure and the internal lattice is filled with a third porous structure to obtain a porous hip pad model 400 for manufacturing the hip pad.

As shown in FIG. 12, with the orientation relative to the user's body when the hip pad is worn as reference for defining an upper surface and a lower surface, and with a TPMS unit cell being configured as a porous structure body, the upper surface lattice is filled with TPMS unit cells 401 which are provided with surface planes, and the lower surface lattice is filled with TPMS unit cells 402 which are provided with surface planes. The difference between the TPMS unit cell 401 and the TPMS unit cell 402 lies in orientations of their surface planes. A TPMS unit cell 403 filled within the edge lattice is provided with a joint region and a surface plane. A body of the porous structure 403 is generated by performing geometric shape blending using volume distance functions of a cylinder and a sphere, a joint region is generated using implicit function representations of adjacent TPMS unit cells, and the orientation of a surface plane of the TPMS unit cell 403 is determined based on the specific location of the lattice.

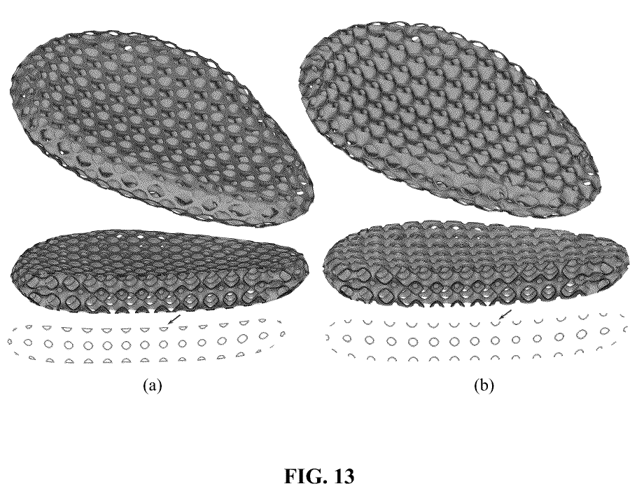

FIG. 13(a) shows a porous hip pad model with a smooth curved surface, and FIG. 13(b) shows a porous hip pad model without a smooth curved surface. The porous hip pad model shown in FIG. 13(a) is generated by modeling according to the above embodiment. In FIG. 13(a), the porous structures filled within the surface lattice and the edge lattice are provided with surface planes, such as the first surface plane and the second surface plane as mentioned above, enabling the porous hip pad model to be provided with smooth curved surface and have a better pore connectivity, significantly improving the wearing comfort, additionally ensuring the hip pad and the hip being closely adhered to each other for exerting excellent shock absorption capability. The porous hip pad model shown in FIG. 13(b) is only filled with a conventional implicit surface, where a connectivity region only exists at edges of the porous structural unit. The hip pad manufactured based on the porous hip pad model shown in FIG. 13(b) exhibits rough surface texture, reduced wear resistance, and poor wearing comfort.

A wearable protective gear modeling system provided according to embodiments of the present disclosure is described below, and the wearable protective gear modeling system described below may be cross-referenced with the wearable protective gear modeling method described above.

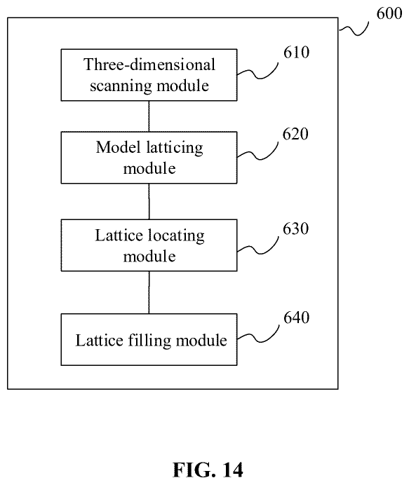

Referring to FIG. 14, the wearable protective gear modeling system 600 includes a three-dimensional scanning module 610, a model latticing module 620, a lattice locating module 630 and a lattice filling module 640.

The three-dimensional scanning module 610 is configured to perform a three-dimensional scan on a wearing position of a user to obtain scanning data.

The model latticing module 620 is configured to construct a latticed protective gear model formed by lattices based on the scanning data.

The lattice locating module 630 is configured to obtain face arrays of the lattices in the latticed protective gear model and determine a surface lattice, an edge lattice, and an internal lattice based on the face arrays of the lattices. The face array indicates a relative positional relationship of faces that form the lattice. The surface lattice forms a non-edge region of a surface of the latticed protective gear model, the edge lattice forms an edge region of the surface of the latticed protective gear model, and the internal lattice forms an internal structure of the latticed protective gear model.

The lattice filling module 640 is configured to fill the surface lattice with a first porous structure, fill the edge lattice with a second porous structure and fill the internal lattice with a third porous structure to obtain a porous protective gear model with a smooth curved surface.

In an embodiment, the model latticing module is further configured to:
construct a solid model of the protective gear and a three-dimensional lattice structure of the protective gear based on the scanning data; and
map the three-dimensional lattice structure of the protective gear to the solid model of the protective gear to obtain the latticed protective gear model.

In an embodiment, the model latticing module is further configured to:
construct a two-dimensional mesh region of the protective gear based on the scanning data; and
extrude the two-dimensional mesh region of the protective gear to obtain the three-dimensional lattice structure of the protective gear.

In an embodiment, the model latticing module is further configured to:
construct a two-dimensional contour of the protective gear based on the scanning data;
generate, through a triangulation algorithm, a two-dimensional triangular mesh region bounded by the two-dimensional contour of the protective gear and filled with first triangular meshes;
reconstruct a connection between the first triangular meshes in the two-dimensional triangular mesh region to generate a hybrid mesh region filled with second triangular meshes and first quadrilaterals;
subdivide the second triangular meshes and the first quadrilateral meshes to generate a quadrilateral mesh region filled with second quadrilateral meshes; and
map the quadrilateral mesh region into the two-dimensional contour of the protective gear and output the two-dimensional mesh region of the protective gear.

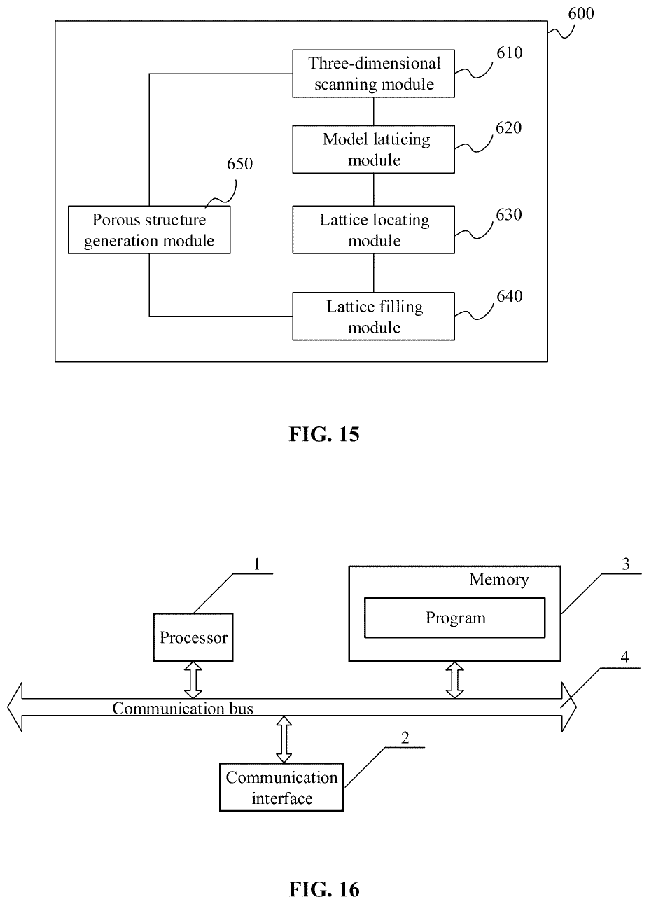

In an embodiment, as shown in FIG. 15, the modeling system 600 further includes a porous structure generation module 650 configured to generate the first porous structure, the second porous structure, and the third porous structure for filling the lattices.

In an embodiment, for generating the first porous structure, the porous structure generation module 650 is further configured to:
generate a first porous structure body through an implicit surface modeling method, and determine a plane where a first pore is located, where the first pore is located on the first porous structure body and faces the surface of the latticed protective gear model;
construct a first quadrilateral plane in the plane where the first pore is located, generate a first trimming region by using an implicit function representation of the first porous structure body, remove the first trimming region from the first quadrilateral plane to form a first contour, where the first contour matches seamlessly with a contour of the first pore, cut four corners of the first quadrilateral plane through subtracting spheres to output a first surface plane, and lattice the first surface plane; and
connect the latticed first surface plane and the first porous structure body to generate the first porous structure, to cause the first surface plane to form a non-edge portion of the surface of the latticed protective gear model.

In an embodiment, the porous structure generation module is further configured to:
calculate an iso-contour line of the implicit function of the first porous structure body in a z-plane; and
generate the first trimming region in the first quadrilateral plane based on the iso-contour line.

In an embodiment, for generating the first porous structure, the porous structure generation module is further configured to:
establish a governing equation of the first porous structure expressed as:

$$⌀ ( x , y , z ) = {Φ}_{P} ( x , y , z ) - N * ( z > k * zi ) ,$$

where Φ(x, y, z) represents an implicit function representation of a first porous structure body, N represents a positive number, and k represents a positive number less than 1; and
generate the first porous structure using the governing equation.

In an embodiment, for generating the second porous structure, the porous structure generation module is further configured to:
generate a second porous structure body through geometric shape blending using volume distance functions of a cylinder and a sphere;
determine a plane where a second pore is located, where the second pore is located on the second porous structure body and faces the surface of the latticed protective gear model;
construct a second quadrilateral plane in the plane where the second pore is located, generate a second trimming region by using a governing equation of the second pore, remove the second trimming region from the second quadrilateral plane to form a second contour, where the second contour matches seamlessly with the contour of the second pore, cut four corners of the second quadrilateral plane through subtracting spheres to output a second surface plane, lattice the second surface plane, and connect the latticed second surface plane and the second porous structure body, to cause the second surface plane to form an edge portion of the surface of the latticed protective gear model; and
generate a joint region by using a governing equation of a porous structure adjacent to the second porous structure body, where the joint region is for connecting the second porous structure with the adjacent porous structure, and connect the joint region and the second porous structure body to generate the second porous structure, where the second porous structure includes the second porous structure body, the second surface plane and the joint region.

In an embodiment, for generating the third porous structure, the porous structure generation module is further configured to:
generate the third porous structure through an implicit surface modeling method.

In an embodiment, the wearable protective gear modeling system further includes a face array generation module, and the face array generation module is configured to:
for each lattice of the lattices,
obtain a vertex array of the lattice, where the vertex array represents positional information of vertices forming the lattice; and
generate a face array of the lattice based on the vertex array.

In an embodiment, the face array generation module is further configured to:
determine face components forming the lattice based on the vertex array of the lattice;
determine a joint face and a non-joint face of the lattice based on the face components, where the joint face is a face shared by adjacent lattices, and the non-joint face is a face forming the lattice other than the joint face;
represent the joint face and the non-joint face of the lattice in a binary manner, and generate the face array of the lattice based on a result represented in the binary manner.

Specific implementation logic of the aforementioned modules may refer to the relevant description of the wearable protective gear modeling method provided according to the aforementioned embodiments, which is not repeated herein.

The wearable protective gear modeling system 600 provided according to the embodiments of the present disclosure may be applied to an electronic device, and FIG. 16 shows a block diagram of a hardware structure of the electronic device. Referring to FIG. 16, the electronic device may include: at least one processor 1, at least one communication interface 2, at least one memory 3, and at least one communication bus 4.

In the embodiments of the present disclosure, the number of the processor 1, the number of the communication interface 2, the number of the memory 3, and the number of the communication bus 4 each are at least one, and the processor 1, the communication interface 2, and the memory 3 communicate with each other via the communication bus 4.

The processor 1 may be a central processing unit (CPU), or an application specific integrated circuit (ASIC), or one or more integrated circuits configured to implement embodiments of the present disclosure, and the like.

The memory 3 may include a high-speed RAM memory, or may include a non-volatile memory and the like, such as at least one disk memory.

The memory stores a program, and the processor may call the program stored in the memory. The program is to implement the processing procedures of the wearable protective gear modeling method described in the aforementioned embodiments.

The wearable protective gear modeling system 600 typically includes a variety of computer-readable media. The computer-readable media may be any available media that can be accessed by the wearable protective gear modeling system 600, including volatile and non-volatile media, and removable or non-removable media. By way of example rather than limitation, the computer-readable media may include computer storage media and communication media. These media store a program executable by a processor, and the program, when executed, may be used to implement the processing procedure according to the aforementioned example aspects, the logic of which may be described with reference to the description of the aforementioned example aspects.

The above embodiments are only used for illustrating the technical solutions of the present disclosure, and are not intended to limit the present disclosure. Although the present disclosure is illustrated in detail with reference to the embodiments described above, it should be understood by those skilled in the art that modification may be made to the technical solutions recited in the embodiments described above, or equivalent substitution may be made onto a part of technical features of the technical solution. The modifications and equivalent replacements will not make the corresponding technical solutions deviate from the spirit and scope of the technical solutions of the embodiments of the present disclosure.

1. A wearable protective gear modeling method, comprising:
performing a three-dimensional scan on a wearing position of a user to obtain scanning data;
constructing a latticed protective gear model formed by lattices based on the scanning data;
obtaining face arrays of the lattices in the latticed protective gear model;
determining a surface lattice, an edge lattice, and an internal lattice based on the face arrays of the lattices, wherein the face array indicates a relative positional relationship of faces that form the lattice, the surface lattice forms a non-edge region of a surface of the latticed protective gear model, the edge lattice forms an edge region of the surface of the latticed protective gear model, and the internal lattice forms an internal structure of the latticed protective gear model; and
filling the surface lattice with a first porous structure, filling the edge lattice with a second porous structure and filling the internal lattice with a third porous structure to obtain a porous protective gear model with a smooth curved surface.

2. The wearable protective gear modeling method according to claim 1, wherein the constructing a latticed protective gear model formed by lattices based on the scanning data comprises:
constructing a solid model of a protective gear and a three-dimensional lattice structure of the protective gear based on the scanning data; and
mapping the three-dimensional lattice structure of the protective gear to the solid model of the protective gear to obtain the latticed protective gear model.

3. The wearable protective gear modeling method according to claim 2, wherein the constructing a three-dimensional lattice structure of the protective gear based on the scanning data comprises:
constructing a two-dimensional mesh region of the protective gear based on the scanning data; and
extruding the two-dimensional mesh region of the protective gear to obtain the three-dimensional lattice structure of the protective gear.

4. The wearable protective gear modeling method according to claim 3, wherein the constructing a two-dimensional mesh region of the protective gear based on the scanning data comprises:
constructing a two-dimensional contour of the protective gear based on the scanning data;
generating, through a triangulation algorithm, a two-dimensional triangular mesh region bounded by the two-dimensional contour of the protective gear and filled with first triangular meshes;
reconstructing a connection between the first triangular meshes in the two-dimensional triangular mesh region to generate a hybrid mesh region filled with second triangular meshes and first quadrilateral meshes;
subdividing the second triangular meshes and the first quadrilateral meshes to generate a quadrilateral mesh region filled with second quadrilateral meshes; and
mapping the quadrilateral mesh region into the two-dimensional contour of the protective gear to output the two-dimensional mesh region of the protective gear.

5. The wearable protective gear modeling method according to claim 1, wherein the first porous structure is generated by:
generating a first porous structure body through an implicit surface modeling method;
determining a plane where a first pore is located, wherein the first pore is located on the first porous structure body and faces the surface of the latticed protective gear model;
constructing a first quadrilateral plane in the plane where the first pore is located;
generating a first trimming region by using an implicit function representation of the first porous structure body, and removing the first trimming region from the first quadrilateral plane to form a first contour, wherein the first contour matches seamlessly with a contour of the first pore;
cutting four corners of the first quadrilateral plane through subtracting spheres to output a first surface plane, and latticing the first surface plane; and
connecting the latticed first surface plane and the first porous structure body to generate the first porous structure, to cause the first surface plane to form a non-edge portion of the surface of the porous protective gear model.

6. The wearable protective gear modeling method according to claim 5, wherein the generating a first trimming region by using an implicit function representation of the first porous structure body comprises:
calculating an iso-contour line of the implicit function representation of the first porous structure body in a z-plane; and
generating the first trimming region in the first quadrilateral plane based on the iso-contour line.

7. The wearable protective gear modeling method according to claim 1, wherein the first porous structure is generated by:
establishing a governing equation of the first porous structure expressed as:
$$⌀ ( x , y , z ) = {Φ}_{P} ( x , y , z ) - N * ( z > k * zi ) ,$$
wherein Φ_{P}(x, y, z) represents an implicit function representation of a first porous structure body, N represents a positive number, and k represents a positive number less than 1; and
generating the first porous structure using the governing equation.

8. The wearable protective gear modeling method according to claim 1, wherein the second porous structure is generated by:
generating a second porous structure body through geometric shape blending using volume distance functions of a cylinder and a sphere;
determining a plane where a second pore is located, wherein the second pore is located on the second porous structure body and faces the surface of the latticed protective gear model;
constructing a second quadrilateral plane in the plane where the second pore is located;
generating a second trimming region by using a governing equation of the second pore, and removing the second trimming region from the second quadrilateral plane to form a second contour, wherein the second contour matches seamlessly with a contour of the second pore;
cutting four corners of the second quadrilateral plane through subtracting spheres to output a second surface plane, and latticing the second surface plane;
connecting the latticed second surface plane and the second porous structure body, to cause the second surface plane to form an edge portion of the surface of the porous protective gear model;
generating a joint region by using a governing equation of a porous structure adjacent to the second porous structure body, wherein the joint region is for connecting the second porous structure with the adjacent porous structure; and
connecting the joint region and the second porous structure body to generate the second porous structure, wherein the second porous structure comprises the second porous structure body, the second surface plane and the joint region.

9. A wearable protective gear modeling system, comprising:
a three-dimensional scanning module, configured to perform a three-dimensional scan on a wearing position of a user to obtain scanning data;
a model latticing module, configured to construct a latticed protective gear model formed by lattices based on the scanning data;
a lattice locating module, configured to obtain face arrays of the lattices in the latticed protective gear model, and determine a surface lattice, an edge lattice, and an internal lattice based on the face arrays of the lattices, wherein the face array indicates a relative positional relationship of faces that form the lattice, the surface lattice forms a non-edge region of a surface of the latticed protective gear model, the edge lattice forms an edge region of the surface of the latticed protective gear model, and the internal lattice forms an internal structure of the latticed protective gear model; and
a lattice filling module, configured to fill the surface lattice with a first porous structure, fill the edge lattice with a second porous structure and fill the internal lattice with a third porous structure to obtain a porous protective gear model with a smooth curved surface.

10. An electronic device, comprising:
a memory storing a computer-executable instruction, and
a processor, wherein
the computer-executable instruction, when executed by the processor, causes the electronic device to perform the wearable protective gear modeling method according to claim 1.

11. A non-transitory readable storage medium, storing a computer-executable program, wherein
the computer-executable program, when being executed, performs the wearable protective gear modeling method according to claim 1.

12. A wearable protective gear, manufactured by using an additive manufacturing technology, wherein the porous protective gear model generated through the wearable protective gear modeling method according to claim 1 is configured as a digital model.
